(19) United States
(12) Patent Application Publication
(10) Pub. No.: US 2026/0130272 A1
(43) Pub. Date: May 7, 2026

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Jongyoun KIM, Suwon-si (KR); Myeonghan BAE, Suwon-si (KR); Minjun BAE, Suwon-si (KR); Minyoung LEE, Suwon-si (KR)

(73) Assignee: SAMSUNG ELECTRONICS CO., LTD., Suwon-si (KR)

(21) Appl. No.: 19/185,920

(22) Filed: Apr. 22, 2025

(30) Foreign Application Priority Data
Nov. 5, 2024 (KR) 10-2024-0154859

(51) Int. Cl. H01L 23/31; H01L 23/00; H01L 23/538; H01L 23/544; H01L 25/11

(52) U.S. Cl. CPC H10W 74/121; H10W 46/00; H10W 90/00; H10W 70/60; H10W 70/611; H10W 90/28; H10W 90/724

(57) ABSTRACT

A semiconductor package includes a redistribution structure including a redistribution layer, chip structures each having a first surface facing the redistribution structure, an interconnection structure between the chip structures and including a connection layer, at least one post configured to electrically connect the connection layer and the redistribution layer, and at least one connecting bump below the redistribution structure. Each chip structure includes semiconductor chips including a front end and a back end opposite to each other in a first direction, side ends opposite to each other in a second direction, and at least one connection pad configured to electrically connect to the connection layer and the redistribution layer, a gap-fill layer covering the semiconductor chips and defining the first surface of the chip structure, and at least one pillar in the gap-fill layer, extending from the at least one connection pad to the first surface.

### CROSS-REFERENCE TO RELATED APPLICATION

This application claims the benefit under 35 USC 119(a) of Korean Patent Application No. 10-2024-0154859 filed on Nov. 5, 2024 in the Korean Intellectual Property Office, the entire disclosure of which is incorporated herein by reference for all purposes.

### BACKGROUND

One or more example embodiments of the disclosure relate to a semiconductor package and a method of manufacturing the same.

As the demand for high capacity, thinness, and miniaturization of electronic products increases, various types of semiconductor packages are being developed. Among these various types of semiconductor packages, a package technology that vertically stacks multiple semiconductor chips is being developed. However, as the number of semiconductor chips stacked increases, a risk during the manufacturing process increases, and it is difficult to secure yield.

### SUMMARY

Example embodiments provide a semiconductor package and a method of manufacturing the same with reduced process difficulty and improved yield.

According to example embodiments, a semiconductor package includes a redistribution structure including a redistribution layer; chip structures stacked vertically on the redistribution structure, and each including a first surface facing the redistribution structure and a second surface opposite the first surface; an interconnection structure between the chip structures, the interconnection structure including a connection layer; a mold layer covering at least portions of the respective chip structures; at least one post within the mold layer and configured to electrically connect the connection layer and the redistribution layer; and at least one connecting bump below the redistribution structure. Each of the chip structures includes semiconductor chips, each including a front end and a back end opposite to the front end in a first direction, side ends opposite to each other in a second direction intersecting the first direction, and at least one connection pad adjacent to the front end and configured to electrically connect to the connection layer and the redistribution layer, a gap-fill layer covering the semiconductor chips and defining the first surface of each of the chip structures, and at least one pillar in the gap-fill layer, the at least one pillar extending from the at least one connection pad to the first surface. The semiconductor chips respectively have different widths from the front end to the back end in the first direction.

According to example embodiments, a semiconductor package includes a redistribution structure including a redistribution layer; chip structures vertically stacked on the redistribution structure; an interconnection structure between the chip structures and including a connection layer; a mold layer surrounding the chip structures; and at least one post within the mold layer and configured to electrically connect to the redistribution layer and the connection layer. Each of the chip structures includes a first semiconductor chip including at least one first connection pad, a first front surface of the first semiconductor chip being on the at least one first connection pad and facing the redistribution structure, a second semiconductor chip including at least one second connection pad and being on the first front surface of the first semiconductor chip, a second front surface of the second semiconductor chip being on the at least one second connection pad and facing the redistribution structure; a gap-fill layer covering the first front surface and the second front surface, at least one first pillar penetrating the gap-fill layer and respectively connected to the at least one first connection pad, and at least one second pillar penetrating the gap-fill layer and respectively connected to the at least one second connection pad. The chip structures include a first chip structure on the interconnection structure, and a second chip structure between the redistribution structure and the interconnection structure. The interconnection structure further includes an insulating layer between the connection layer and the first chip structure, and at least one connecting via penetrating the insulating layer and connecting the connection layer to the at least one first pillar and the at least one second pillar of the first chip structure.

According to example embodiments, a method of manufacturing a semiconductor package includes forming a cover layer and an alignment pattern on a carrier substrate; attaching a first chip structure on the cover layer; forming a first mold layer covering the first chip structure; forming an interconnection structure on the first mold layer and the first chip structure; forming at least one post on the interconnection structure; attaching a second chip structure on the interconnection structure around the at least one post; forming a second mold layer covering the at least one post and the second chip structure; and forming a redistribution structure on the second mold layer and the second chip structure. Each of the first chip structure and the second chip structures includes a first semiconductor chip including at least one first connection pad, a first front surface of the first semiconductor chip being on the at least one first connection pad and facing upwards, a second semiconductor chip including at least one second connection pad and being on the first front surface, a second front surface of the second semiconductor chip being on the at least one second connection pad and facing upwards, a gap-fill layer covering the first front surface and the second front surface, at least one first pillar penetrating the gap-fill layer and respectively connected to the at least one first connection pad, and at least one second pillar penetrating the gap-fill layer and respectively connected to the at least one second connection pad. The interconnection structure includes a connection layer configured to electrically connect the at least one post to the at least one first pillar and the at least one second pillar of the first chip structure. The redistribution structure includes a redistribution layer configured to electrically connect to the at least one post and the at least one first pillar and the at least one second pillar of the second chip structure.

According to example embodiments, a semiconductor package includes: a redistribution structure including a redistribution layer; chip structures stacked vertically on the redistribution structure, and each including a first surface facing the redistribution structure and a second surface opposite the first surface; an interconnection structure between the chip structures, the interconnection structure including a connection layer; a mold layer covering at least portion of each of the chip structures; at least one post within the mold layer and configured to electrically connect the connection layer and the redistribution layer; and at least one connecting bump below the redistribution structure, wherein each of the chip structures includes: semiconductor chips vertically stacked; a gap-fill layer covering at least a portion of each of the semiconductor chips; and at least one pillar in the gap-fill layer, the at least one pillar configured to electrically connect the each of the semiconductor chips to the connection layer or the redistribution layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view of a semiconductor package according to one or more example embodiments, FIG. 1B is a cross-sectional view taken along line I-I′ of FIG. 1A, and FIG. 1C is a cross-sectional view taken along line II-II′ of FIG. 1A;

FIG. 2A is a cross-sectional view of a chip structure according to one or more example embodiments, and FIG. 2B is a bottom view of the chip structure of FIG. 2A;

FIG. 2C is a cross-sectional view of a chip structure according to one or more example embodiments, and FIG. 2D is a bottom view of the chip structure of FIG. 2C;

FIG. 3 is a cross-sectional view of a semiconductor package according to one or more example embodiments

FIG. 4 is a cross-sectional view of a semiconductor package according to one or more example embodiments;

FIG. 5 is a flowchart illustrating a method of manufacturing a chip structure according to one or more example embodiments;

FIGS. 6A to 6F are drawings illustrating a method of manufacturing a chip structure of FIG. 5;

FIG. 7 is a flowchart illustrating a method of manufacturing a semiconductor package according to one or more example embodiments; and

FIGS. 8A to 8G are drawings illustrating a method of manufacturing the semiconductor package of FIG. 7.

### DETAILED DESCRIPTION

Hereinafter, with reference to the accompanying drawings, example embodiments of the present disclosure will be described as follows. Unless otherwise specified, in this specification, terms such as ‘upper portion,’ ‘upper surface,’ ‘lower portion,’ ‘lower surface,’ ‘side,’ ‘side surface’ and the like are based on the drawings, and actually, may vary depending on the direction in which the components are disposed.

Additionally, ordinal numbers such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. Additionally, terms (for example, “first” in a specific claim) referenced by a specific ordinal number may be described elsewhere with a different ordinal number (for example, “second” in the specification or another claim). Expressions such as “at least one of”, when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

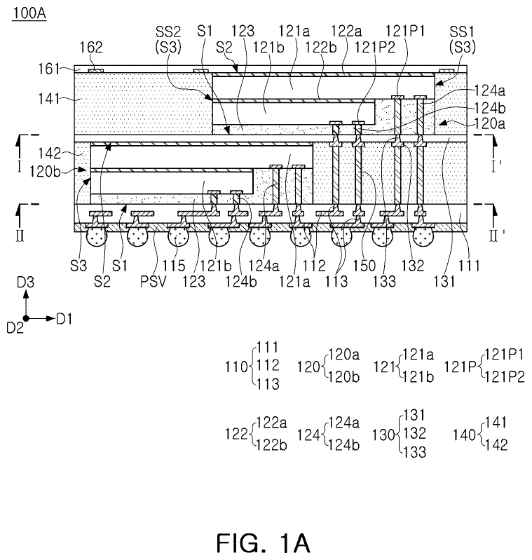

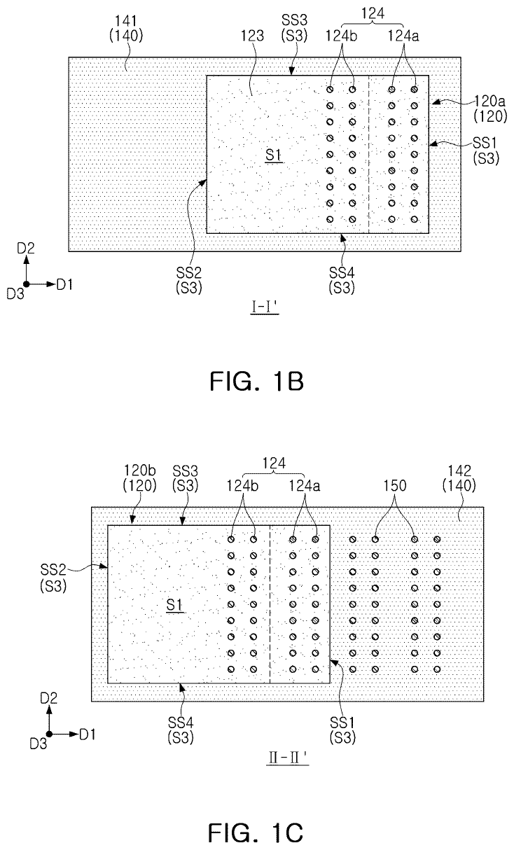

FIG. 1A is a cross-sectional view of a semiconductor package 100A according to one or more example embodiments, FIG. 1B is a cross-sectional view taken along line I-I′ of FIG. 1A, and FIG. 1C is a cross-sectional view taken along line II-II′ of FIG. 1A.

Referring to FIGS. 1A to 1C, the semiconductor package 100A according to one or more example embodiments may include a redistribution structure 110, chip structures 120, an interconnection structure 130, a mold layer 140, and posts 150. According to an example embodiment, the semiconductor package 100A may further include a cover layer 161 and an alignment pattern 162.

The redistribution structure 110 may redistribute the chip structures 120 to electrically connect the same to an external device. The redistribution structure 110 may include an insulating layer 111, a redistribution layer 112, and redistribution vias 113. Connecting bumps 115 may be disposed below the redistribution structure 110. The connecting bumps 115 may be electrically connected to the redistribution layer 112. The semiconductor package 100A may be connected to an external device such as a module substrate, a main board, or the like through the connecting bumps 115. The connecting bumps 115 may include, for example but not limited to, tin (Sn) or an alloy (Sn—Ag—Cu) containing tin (Sn). In some embodiments, the connecting bumps 115 may have a form in which a pillar (or underbump metal) and a solder ball are combined. According to an example embodiment, a passivation layer (PSV) may be formed on a lower surface of the redistribution structure 110 to protect the redistribution layer 112 and the connecting bumps 115 from physical and/or chemical damage.

The insulating layer 111 may include an insulating resin. The insulating resin may include, for example but not limited to, a thermosetting resin such as an epoxy resin, a thermoplastic resin such as a polyimide, or a resin impregnated with an inorganic filler, such as prepreg, Ajinomoto Build-up Film (ABF), Flame Resistant (FR-4), or Bismaleimide-Triazine (BT). For example, the insulating layer 111 may include a photosensitive resin such as Photoimageable Dielectric (PID). The insulating layer 111 may include insulating layers laminated in a vertical direction D3, but a boundary between the insulating layers may be unclear depending on a process.

The redistribution layer 112 may be disposed on or within the insulating layer 111. The redistribution layer 112 may include a metal, for example but not limited to, copper (Cu), aluminum (Al), silver (Ag), tin (Sn), gold (Au), nickel (Ni), lead (Pb), titanium (Ti), or any alloy thereof. The redistribution layer 112 may include a ground pattern, a power pattern, and/or a signal pattern. In this case, the signal pattern may provide a transmission path for various signals, for example, a data signal, excluding the ground pattern, the power pattern, and the like. The redistribution layer 112 may include more or fewer redistribution layers than those illustrated in the drawing.

The redistribution vias 113 may be disposed within the insulating layer 111. The redistribution vias 113 may electrically connect redistribution layers 112 on different levels, or electrically connect the redistribution layers 112 to pillars 124 and the posts 150. The redistribution vias 113 may extend integrally from the redistribution layer 112 and may contact the pillars 124 and the posts 150. The redistribution vias 113 may have a tapered shape toward corresponding pillars 124 and corresponding posts 150. The redistribution vias 113 may include a metal material including, for example but not limited to, copper (Cu), aluminum (Al), silver (Ag), tin (Sn), gold (Au), nickel (Ni), lead (Pb), titanium (Ti), or any alloy thereof. The redistribution vias 113 may be filled vias in which a metal material is filled inside a via hole or conformal vias in which a metal material extends along an inner wall of the via hole.

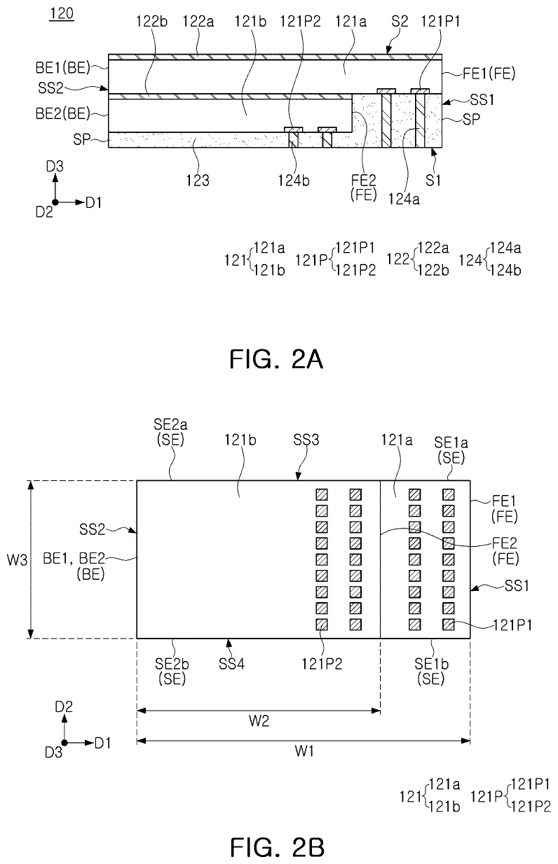

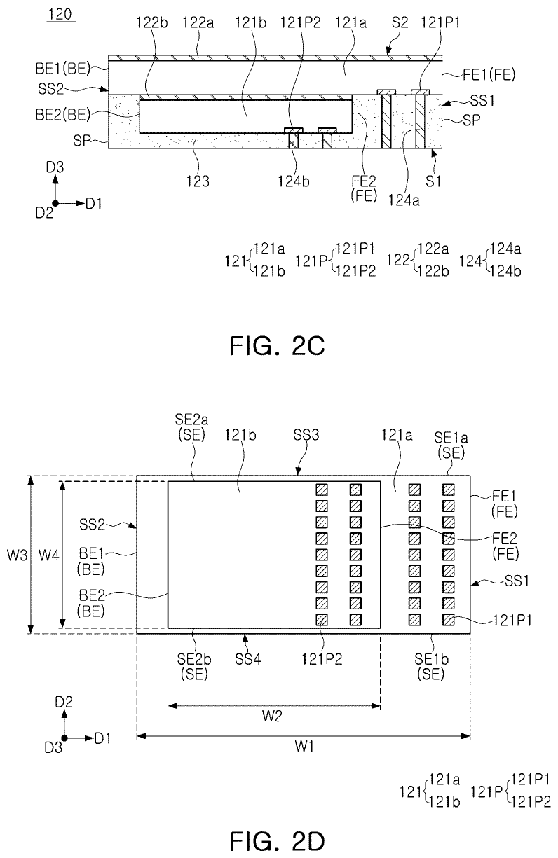

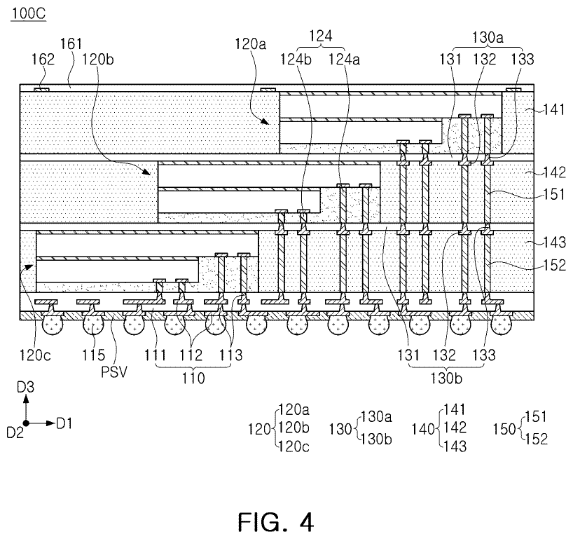

The chip structures 120 may be disposed on the redistribution structure 110. The chip structures 120 may be stacked in the vertical direction D3. The chip structures 120 may be offset such that the pillars 124 are exposed in the vertical direction D3. For example, the chip structures 120 may include a first chip structure 120a on the interconnection structure 130, and a second chip structure 120b between the redistribution structure 110 and the interconnection structure 130. The first chip structure 120a may be offset in a horizontal direction, for example, in a first direction D1, with respect to the second chip structure 120b. The chip structures 120 may be provided in a greater number than those illustrated in the drawing (see e.g., FIG. 4). According to an example embodiment, the semiconductor package 100A may include chip structures 120 of different shapes. For example, in the semiconductor package 100A, one of the first chip structure 120a and the second chip structure 120b may be a chip structure 120′ of a modified example illustrated in FIG. 2C described below (see e.g., FIGS. 2C and 2D).

The chip structures 120 may each include a first surface S1 facing the redistribution structure 110, a second surface S2 opposite to the first surface S1, and a third surface S3 between the first surface S1 and the second surface S2. The first surface S1 may be understood as a lower surface of the chip structure 120 where the pillars 124 are exposed (based on FIG. 1A). The second surface S2 may be understood as an upper surface of the chip structure 120 where an attachment film (or adhesive film) 122 is exposed (based on FIG. 1A). The third surface S3 may be understood as side surfaces SS1, SS2, SS3 and SS4 of the chip structure 120 that define a boundary between the chip structure 120 and the mold layer 140 (based on FIG. 1A). For example, the chip structure 120 may include a first side surface SS1, a second side surface SS2, a third side surface SS3, and a fourth side surface SS4.

According to an example embodiment, chip structures 120 on which semiconductor chips 121 are already laminated may be manufactured separately, and accordingly, a number of times the chip structures 120 are laminated may be reduced compared to a number of semiconductor chips 121 embedded in the semiconductor package 100A. As a result, a process risk may be reduced and yield may be improved. Each of the chip structures 120 may include semiconductor chips 121, the attachment films 122, a gap-fill layer 123, and the pillars 124.

The semiconductor chips 121 may include nonvolatile memory chips such as, for example but not limited to, a flash memory, a phase-change random access memory (PRAM), a magnetoresistive random access memory (MRAM), a ferroelectric random access memory (FeRAM), or a resistive random access memory (RRAM), and/or volatile memory chips such as a dynamic random access memory (DRAM) or a static random access memory (SRAM). The semiconductor chips 121 may include memory chips of the same type, but are not limited thereto. According to an example embodiment, a plurality of semiconductor chips 121 may include memory chips of different types. In some embodiments, the semiconductor chips 121 may include logic chips such as, for example but not limited to, a central processor (CPU), a graphics processor (GPU), a field programmable gate array (FPGA), an application processor (AP), a digital signal processor (DSP), a cryptographic processor, a microprocessor, a microcontroller, an analog-to-digital converter, an application-specific IC (ASIC), and the like.

The semiconductor chips 121 may be disposed such that connection pads 121P face the first surface S1 of the chip structure 120. The semiconductor chips 121 may be stacked such that a lower surface on which the connection pads 121P are disposed faces the redistribution structure 110. The semiconductor chips 121 may be offset such that the connection pads 121P are exposed in the vertical direction D3. The connection pads 121P may include, for example but not limited to, one of copper (Cu), nickel (Ni), titanium (Ti), aluminum (Al), or any alloy thereof.

The attachment films 122 may be disposed on respective upper surfaces of the semiconductor chips 121 (based on FIG. 1A). The attachment films 122 may include or be formed of synthetic resins such as, for example but not limited to, epoxy resin, phenol resin, melamine resin, polyester resin, silicone resin, urethane resin, polyamide resin, and acrylic resin. The attachment films 122 may be, for example but are not limited to, Die Attach Film (DAF). According to an example embodiment, the attachment films 122 may include thermally conductive fillers such as, for example but not limited to, alumina (Al₂O₃), aluminum nitride (AlN), boron nitride (BN), magnesium oxide (MgO), zinc oxide (ZnO), silica (SiO₂), and the like.

The gap-fill layer 123 may cover the connection pads 121P of the semiconductor chips 121. The gap-fill layer 123 may define the first surface S1 and the side surfaces SS1, SS2, SS3 and SS4 of the chip structures 120. The gap-fill layer 123 may surround the pillars 124 and electrically isolate the pillars 124. The gap-fill layer 123 may include an insulating material, for example but not limited to, prepreg, ABF, FR-4, BT, or Epoxy Molding Compound (EMC). In some embodiments, the gap-fill layer 123 may include silicon oxide, silicon nitride, or the like.

The pillars 124 may be disposed within the gap-fill layer 123. The pillars 124 may penetrate the gap-fill layer 123 and be connected to the connection pads 121P of the semiconductor chips 120. The pillars 124 may include, for example but not limited to, copper (Cu), aluminum (Al), silver (Ag), tin (Sn), gold (Au), nickel (Ni), lead (Pb), titanium (Ti), or any alloy thereof. The pillars 124 may have a cylindrical shape extending in the vertical direction D3, but are not limited thereto. In some embodiments, the pillars 124 may be bonding wires formed using a capillary. In this case, the pillars 124 may include, for example but not limited to, gold (Au), silver (Ag), lead (Pb), aluminum (Al), copper (Cu), or any alloy thereof. The pillars 124 may be exposed to the first surface S1 of the chip structure 120. Bottom surfaces of the pillars 124 may define the first surface S1 of the chip structure 120 together with the gap-fill layer 123.

In an example embodiment, the semiconductor chips 121 may include a first semiconductor chip 121a including first connection pads 121P1 and a second semiconductor chip 121b including second connection pads 121P2. The first semiconductor chip 121a may be disposed such that a first front surface (‘lower surface’ of the first semiconductor chip 121a in FIG. 1A) on which the first connection pads 121P1 are disposed faces the redistribution structure 110. The second semiconductor chip 121b may be disposed on the first front surface of the first semiconductor chip 121a such that a second front surface (‘lower surface’ of the second semiconductor chip 121b in FIG. 1A) of the second semiconductor chip 121b on which the second connection pads 121P2 are disposed faces the redistribution structure 110.

In an example embodiment, the attachment films 122 may include a first attachment film 122a disposed on a first back surface (‘upper surface’ of FIG. 1A) of the first semiconductor chip 121a, and a second attachment film 122b disposed on a second back surface (‘upper surface’ of FIG. 1A) of the second semiconductor chip 121b.

In an example embodiment, the pillars 124 may include first pillars 124a penetrating the gap-fill layer 123 covering the first front surface of the first semiconductor chip 121a and connected to the first connection pads 121P1, and second pillars 124b penetrating the gap-fill layer 123 covering the second front surface of the second semiconductor chip 121b and connected to the second connection pads 121P2. A height of the first pillars 124a may be greater than a height of the second pillars 124b. The height of the first pillars 124a may be greater than a thickness of the second semiconductor chip 121b. The height of the first pillars 124a may be about 100 μm or more, but is not limited thereto.

According to an example embodiment, the chip structures 120 may include a greater number of the semiconductor chips 121, the attachment films 122, and the pillars 124 than those illustrated in the drawing. The chip structures 120 will be described in more detail later with reference to FIGS. 2A and 2B for features thereof.

The interconnection structure 130 may be disposed between the chip structures 120. For example, the interconnection structure 130 may be disposed between the first chip structure 120a and the second chip structure 120b. The interconnection structure 130 may include an insulating layer 131, a connection layer 132, and connecting vias 133. According to an example embodiment, the interconnect structure 130 may include a greater number of the insulating layers 131, the connection layers 132, and the connecting vias 133 than those illustrated in the drawing. The insulating layers 131, the connection layers 132, and the connecting vias 133 of the interconnect structure 130 may have similar characteristics to the insulating layers 111, the redistribution layers 112, and the redistribution vias 113 of the redistribution structure 110, respectively, and therefore, a duplicate description will be omitted.

The insulating layer 131 may include a material the same as or similar to the insulating layer 111 of the redistribution structure 110. The insulating layer 131 may include, for example but not limited to, a photosensitive resin such as prepreg, ABF, FR-4, BT, or PID. The connection layer 132 may be disposed on or within the insulating layer 131. The connection layer 132 may include a metal, for example but not limited to, copper (Cu), aluminum (Al), silver (Ag), tin (Sn), gold (Au), nickel (Ni), lead (Pb), titanium (Ti), or any alloy thereof. The connecting vias 133 may be disposed in the insulating layer 131. The connecting vias 133 may electrically connect connection layers 132 at different levels, or electrically connect the connection layers 132 to the pillars 124. The connecting vias 133 may extend integrally from the connection layer 132 and may contact the pillars 124. The connecting vias 133 may have a shape that is tapered toward corresponding pillars 124. The connecting vias 133 may be filled vias in which a metal material is filled inside a via hole or conformal vias in which a metal material extends along an inner wall of the via hole.

The mold layer 140 may cover respective peripheries of the chip structures 120. The mold layer 140 may surround the chip structures 120 and may be in contact with the side surfaces SS1, SS2, SS3 and SS4 of the chip structures 130. For example, the mold layer 140 may include a first mold layer 141 surrounding the first chip structure 120a and a second mold layer 142 surrounding the second chip structure 120b. The mold layer 140 may include, for example but not limited to, prepreg, ABF, FR-4, BT, EMC, or the like. The mold layer 140 may include the same material as the gap-fill layer 123 of the chip structures 120. In some embodiments, the mold layer 140 may include a different material than the gap-fill layer 123 of the chip structures 120.

The posts 150 may be positioned within the mold layer 140. The posts 150 may provide an electrical connection path between the interconnection structure 130 and the redistribution structure 110. For example, the posts 150 may penetrate the second mold layer 142 and electrically connect the interconnection layer 132 and the redistribution layer 112. The posts 150 may include, for example but not limited to, copper (Cu), aluminum (Al), silver (Ag), tin (Sn), gold (Au), nickel (Ni), lead (Pb), titanium (Ti), or any alloy thereof. The posts 150 may have a cylindrical shape extending in the vertical direction D3, but are not limited thereto. The posts 150 may be exposed to a lower surface of the second mold layer 142.

The cover layer 161 may be disposed on an uppermost chip structure (for example, 120a). In this case, the ‘uppermost chip structure’ may refer to the first chip structure 120a located farthest from the redistribution structure 110 among the vertically arranged chip structures 120. The cover layer 161 may include a material the same as or similar to the insulating layers 111, 131, for example, a photosensitive resin such as PID. The alignment pattern 162 may be disposed within the cover layer 161. The alignment pattern 162 may be an alignment key for determining an attachment position of the chip structures 120. For example, the alignment pattern 162 may be disposed on the first mold layer 141 and the first chip structure 120a.

FIG. 2A is a cross-sectional view of a chip structure 120 of one or more example embodiments, and FIG. 2B is a bottom view of the chip structure 120 of FIG. 2a. In FIG. 2B, the gap-fill layer 123 and the pillars 124 of FIG. 2A are omitted.

FIG. 2C is a cross-sectional view of the chip structure 120′ of an illustrative modified example, and FIG. 2D is a bottom view of the chip structure 120′ of FIG. 2C. In FIG. 2D, the gap-fill layer 123 and the pillars 124 of FIG. 2C are omitted.

Referring to FIGS. 2A and 2B, in the chip structure 120 of one or more example embodiments, the semiconductor chips 121 may include a front end FE and a back end BE positioned opposite to each other in the first direction D1, and side ends SE positioned opposite to each other in a second direction D2 intersecting the first direction D1. The connection pads 121P may be arranged adjacent to the front ends FE of the chip structure 120. The front ends FE of the semiconductor chips 120 may be offset such that the connection pads 121P are exposed. Side portions SP of the gap-fill layer 123 may be coplanar with the front ends FE, the back ends BE, and the side ends SE of the semiconductor chips 121. The pillars 124 may extend from the connection pads 121P to the first surface S1 of the chip structure 120.

The semiconductor chips 121 may have different sizes (widths, planar areas, or the like). The semiconductor chips 121 may have different widths in at least one direction. For example, a largest width (for example, W1) among widths W1 and W2 of the semiconductor chips 121 in the first direction D1 may be equal to a width of the gap-fill layer 123 in the first direction D1.

In an example embodiment, respective widths of the semiconductor chips 121 from the front ends FE to the back ends BE may be different from each other. Respective back ends BE of the semiconductor chips 121 may be aligned with the second side surface SS2 of the chip structure 120. The back ends BE of the semiconductor chips 121 may form a coplanar surface. The side surfaces SS1, SS2, SS3 and SS4 of the chip structure 120 may be defined by the front end FE, the back end BE, and the side ends SE of the semiconductor chips 121 and the side portions SP of the gap-fill layer 123. Widths W3 between the side ends SE of the semiconductor chips 121 may be the same. Respective side ends SE of the semiconductor chips 121 may be aligned with the third side surface SS3 and the fourth side surface SS4 of the chip structure 120.

In an example embodiment, the first semiconductor chip 121a may include a first front end FE1 adjacent to the first connection pads 121P1 and a first back end BE1 positioned opposite the first front end FE1, and the second semiconductor chip 121b may include a second front end FE2 adjacent to the second connection pads 121P2 and a second back end BE2 positioned opposite the second front end FE2. In addition, the first semiconductor chip 121a may include a first side end SE1a and a second side end SE1b, and the second semiconductor chip 121b may include a third side end SE2a and a fourth side end SE2b.

The first connection pads 121P1 may be arranged adjacent to the first front end FE1 of the first chip structure 120a. The second connection pads 121P2 may be arranged adjacent to the second front end FE2 of the second chip structure 120b. The first front end FE1 of the first chip structure 120a and the second front end FE2 of the second chip structure 120b may be offset such that the first connection pads 121P1 are exposed. The first back end BE1 of the first chip structure 120a and the second back end BE2 of the second chip structure 120b may be coplanar with the side portion SP of the gap-fill layer 123 and may define the side surface of the chip structure 120.

The first side surface SS1 of the chip structures 120 may be adjacent to the first front end FEL and the second front end FE2. The second side surface SS2 of the chip structures 120 may be adjacent to the first back end BE1 and the second back end BE2. The third side surface SS3 of the chip structures 120 may be adjacent to the first side end SE1a and the third side end SE2a. The fourth side surface SS4 of the chip structures 120 may be adjacent to the second side end SE1b and the fourth side end SE2b. In an example embodiment, the first side surface SS1, the second side surface SS2, the third side surface SS3, and the fourth side surface SS4 of the chip structures 120 may be defined by at least one of the first front end FE1, the second front end FE2, the first back end BE1, the second back end BE2, the first side end SE1a, the second side end SE1b, the third side end SE2a, and the fourth side end SE2b, and the side portion SP of the gap-fill layer 123.

Referring to FIGS. 2C and 2D, in the chip structure 120′ of an illustrative modified example, the gap-fill layer 123 may define at least two or more side surfaces of the chip structure 120′, for example, a first side surface SS1, a second side surface SS2, a third side surface SS3, and a fourth side surface SS4. In a variation, the back end BE and the side end SE of each of the semiconductor chips 121 may be offset in the vertical direction D3. The second side surface SS2 of the chip structures 120′ may be defined by the first back end BE1 and the side portion SP of the gap-fill layer 123. Similarly, when a fourth width W4 of the second semiconductor chip 121b in the second direction D2 is smaller than the third width W3 of the first semiconductor chip 121a in the second direction D2, the third side surface SS2 and/or the fourth side surface SS4 of the chip structures 120′ may be defined by the first side end SE1a, the second side end SE1b, and the side portion SP of the gap-fill layer 123.

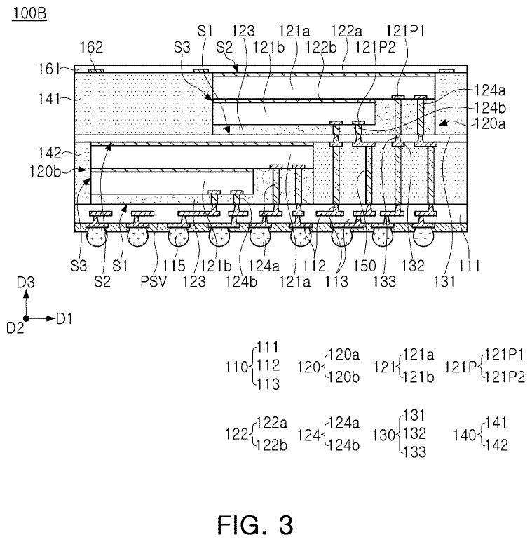

FIG. 3 is a cross-sectional view of a semiconductor package 100B according to one or more example embodiments.

Referring to FIG. 3, the semiconductor package 100B of an example embodiment may have the same or similar features as described with reference to FIG. 1A to 2B, except that the interconnection structure 130 may redistribute the pillars 124. The interconnection structure 130 may include a connection layer 132 patterned in the horizontal direction D1 and D2. At least some of the posts 150 connected to one end of the patterned connection layer 132 may not overlap with the electrically connected pillars 124 in the vertical direction D3. Accordingly, the posts 150 may be positioned regardless of positions of the pillars 124, thereby reducing congestion of the posts 150 and the redistribution layer 112, and increasing a design freedom of the redistribution layer 112.

FIG. 4 is a cross-sectional view of a semiconductor package 100C according to one or more example embodiments.

Referring to FIG. 4, the semiconductor package 100C of one or more example embodiments may have the same or similar features as those described with reference to FIGS. 1A to 3, except for a number of chip structures 120.

In an example embodiment, the chip structures 120 may include a first chip structure 120a, a second chip structure 120b, and a third chip structure 120c. The first chip structure 120a, the second chip structure 120b, and the third chip structure 120c may be offset such that respective pillars 124 thereof are exposed.

The interconnection structure 130 may include a first interconnection structure 130a disposed between the first chip structure 120a and the second chip structure 120b, and a second interconnection structure 130b disposed between the third chip structure 120b and the third chip structure 120c. The first interconnection structure 130a and the second interconnection structure 130b may each include an insulating layer 131, a connection layer 132, and connecting vias 133.

The mold layer 140 may include a first mold layer 141 surrounding the first chip structure 120a, a second mold layer 142 surrounding the second chip structure 120b, and a third mold layer 143 surrounding the third chip structure 120c.

The posts 150 may include first posts 151 in the second mold layer 142 and second posts 152 in the third mold layer 143. The first posts 151 may penetrate the second mold layer 142 and electrically connect the connection layer 132 of the first interconnection structure 130a and the connection layer 132 of the second interconnection structure 130b. The second posts 152 may penetrate the third mold layer 143 and electrically connect the connection layer 132 of the second interconnection structure 130b and the redistribution layer 112 of the redistribution structure 110.

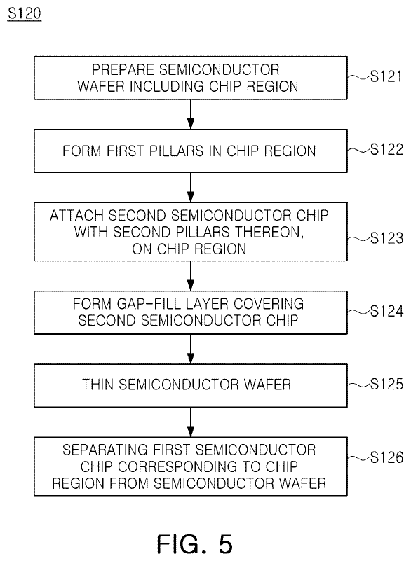

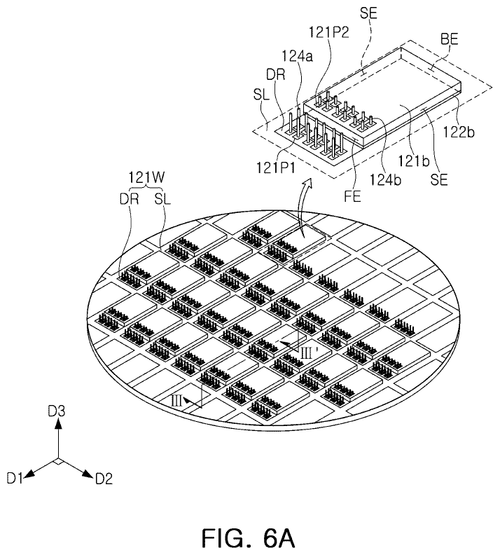

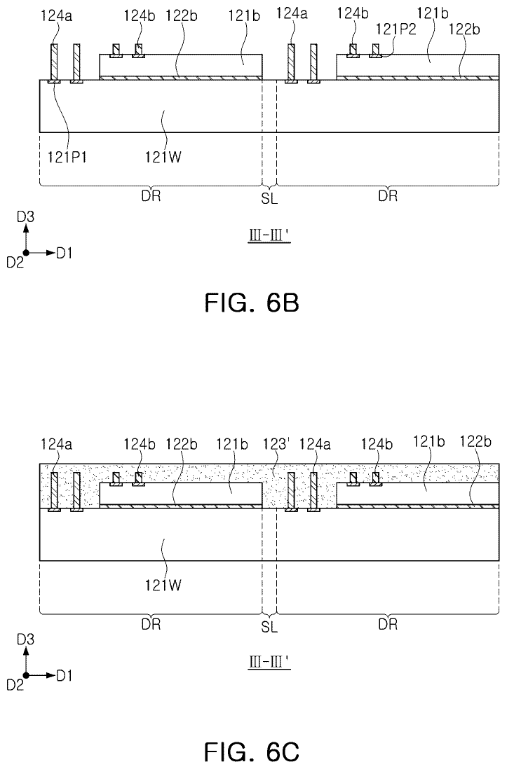

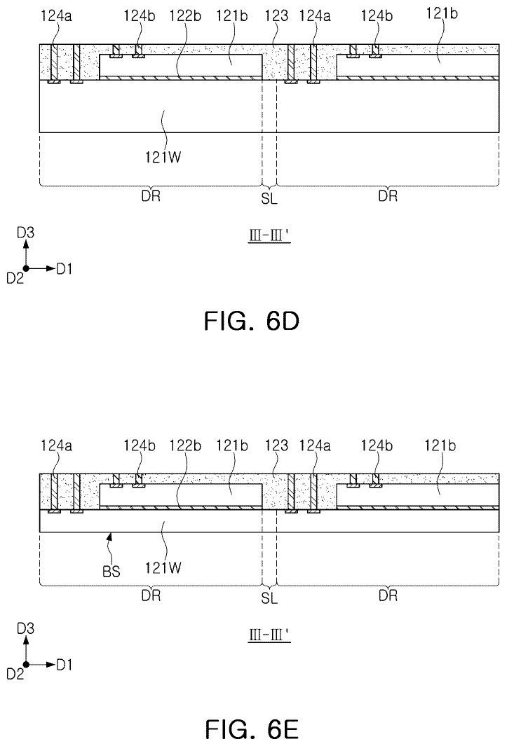

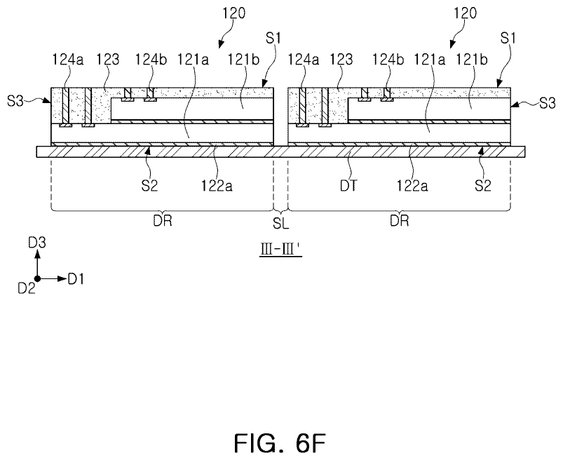

FIG. 5 is a flow chart illustrating a method (S120) of manufacturing a chip structure according to one or more example embodiments, and FIGS. 6A to 6F are drawings illustrating a method (S120) of manufacturing a chip structure in FIG. 5. FIGS. 6B to 6F illustrate a region cut along line III-III′ of FIG. 6A.

Referring to FIG. 5, the method (S120) of manufacturing a chip structure may include an operation of preparing a semiconductor wafer including a chip region (S121), an operation of forming first pillars in the chip region (S122), an operation of attaching a second semiconductor chip, on which second pillars are formed, on the chip region (S123), an operation of forming a gap-fill layer covering the second semiconductor chip (S124), an operation of thinning the semiconductor wafer (S125), and an operation of separating the first semiconductor chip corresponding to the chip region from the semiconductor wafer (S126).

Referring to FIGS. 5, 6A, and 6B, first pillars 124a may be formed on a semiconductor wafer 121W. The semiconductor wafer 121W may include device regions DR (or referred to as ‘chip regions’) divided by scribe lanes SL. The semiconductor wafer 121W may be a silicon wafer having integrated circuits formed in the device regions DR. The first pillars 124a may be formed on first connection pads 121P1 in the device regions DR. The first pillars 124a may be formed using a photolithography process, a plating process, an etching process, or the like. The first pillars 124a may be formed to have a height greater than a thickness of second semiconductor chips 121b to be placed thereafter. In an example embodiment, the first pillars 124a may be formed before the second semiconductor chips 121b are attached. Accordingly, a process risk due to the step of the second semiconductor chips 121b may be reduced.

Second semiconductor chips 121b having second pillars 124b formed within the device regions DR may be placed. The second semiconductor chips 121b may be placed such that second connection pads 121P2 face upward. The second semiconductor chips 121b may be attached to the semiconductor wafer 121W by a second attachment film 122b. The second pillars 124b may be formed on the second connection pads 121P2 of the second semiconductor chips 121b. A height of the second pillars 124b may be smaller than a height of the first pillars 124a. The second semiconductor chips 121b may include the same type of an integrated circuit as the device regions DR. For example, when the second semiconductor chips 121b and the device regions DR include the same type of a memory circuit (for example, DRAM circuit), that is, when areas on which the integrated circuits are formed are substantially the same in the second semiconductor chips 121b and the device regions DR, the device regions DR may include a dummy region that is larger than the second semiconductor chips 121b on the back end BE of the second semiconductor chips 121b. In this case, the ‘dummy region’ may be understood as a region in which the integrated circuit is not formed, or a residual portion of a scribe region after a dicing process, or the like. In some embodiments, the second semiconductor chips 121b and the device regions DR may include different types of integrated circuits. For example, the second semiconductor chips 121b and the device regions DR may include different types of memory circuits, or may include memory circuits and logic circuits, respectively.

The second semiconductor chip 121b may be positioned on a boundary between the device region DR and the scribe lane SL in at least one direction, excluding a direction in which the first pillars 124a are arranged, or may be positioned on the scribe lane SL outside the device region DR. For example, at least one of the back end BE and the side ends SE of the second semiconductor chip 121b, excluding the front end FE, may overlap the scribe lane SL beyond the device region DR. In this case, the back end BE and the side ends SE of the second semiconductor chip 121b may form a side surface (third surface (S3)) of the chip structure in the dicing process (see FIGS. 2A and 2B). In some embodiments, at least one of the back end BE and the side ends SE of the second semiconductor chip 121b, excluding the front end FE, may be located inside the device region DR. In this case, the back end BE and the side ends SE of the second semiconductor chip 121b may not form a side surface (third surface (S3)) of the chip structure in the dicing process (see FIGS. 2C and 2D).

Referring to FIGS. 5 and 6C, a gap-fill material layer 123′ may be formed on the semiconductor wafer 121W. The gap-fill material layer 123′ may fill gaps between the second semiconductor chips 121b and cover the first pillars 124a and the second pillars 124b. The gap-fill material layer 123′ may be formed by coating and curing a gap-fill material such as EMC on the semiconductor wafer 121W. In some embodiments, the gap-fill material layer 123′ may be formed by depositing a gap-fill material such as silicon oxide.

Referring to FIGS. 5 and 6D, a gap-fill layer 123 covering the second semiconductor chips 121b may be formed. The gap-fill layer 123 may be formed by applying a grinding process to the gap-fill material layer 123′. The gap-fill layer 123 may be formed to form a coplanar surface with upper surfaces of the first pillars 124a and the second pillars 124b. The first pillars 124a and the second pillars 124b may be exposed through ground surface of the gap-fill layer 123.

Referring to FIGS. 5 and 6E, the semiconductor wafer 121W may be thinned. A backside BS of the semiconductor wafer 121W on which second semiconductor chips 121b are not disposed may be ground. The semiconductor wafer 121W may be thinned to a designed thickness by a backgrinding process.

Referring to FIGS. 5 and 6F, first semiconductor chips 121a may be separated from the semiconductor wafer 121W. The semiconductor wafer 121W may be cut along a scribe lane SL after bonding a first attachment film 122a and a dicing tape DT to the backside BS of the semiconductor wafer 121W. The first semiconductor chips 121a may include device regions DR separated by the dicing process. On a back surface of the first semiconductor chips 121a, the first attachment films 122a separated by a dicing process may be disposed.

In this manner, according to the manufacturing method (S120) of the chip structure of an example embodiment, chip structures 120 including the first semiconductor chip 121a, the second semiconductor chip 121b, the first attachment film 122a, the second attachment film 122b, the gap-fill layer 123, the first pillars 124a, and the second pillars 124b may be formed. In addition, the chip structures 120 may include a first surface S1 on which the first pillars 124a and the second pillars 124b are exposed, a second surface S2 on which the first attachment film 122a is exposed, and a third surface S3 defining an edge of the chip structures 120 between the first surface S1 and the second surface S2.

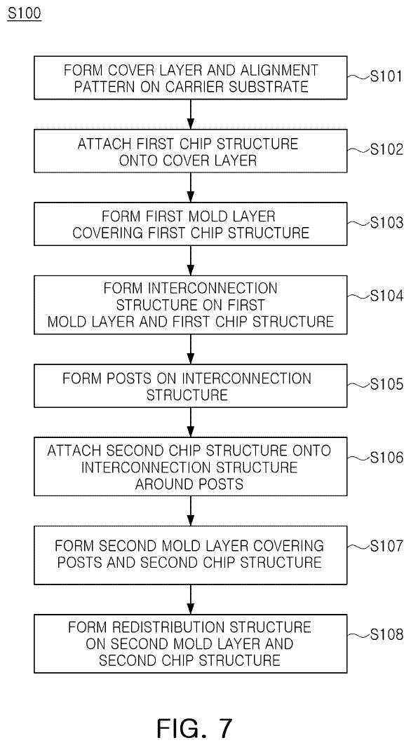

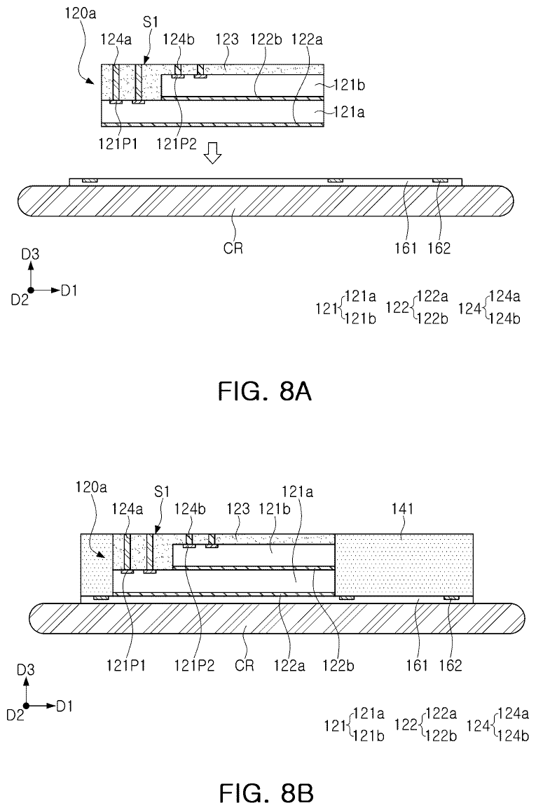

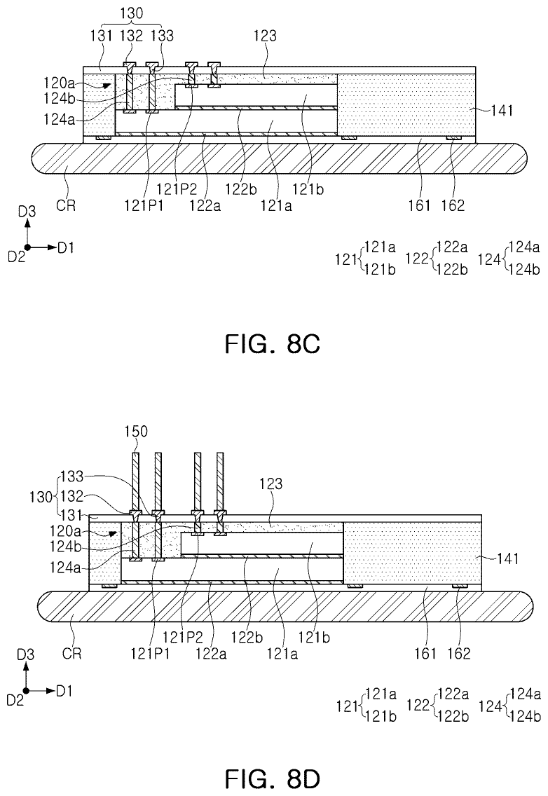

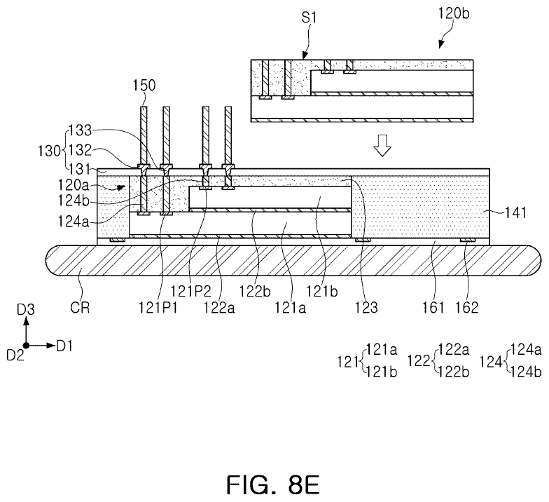

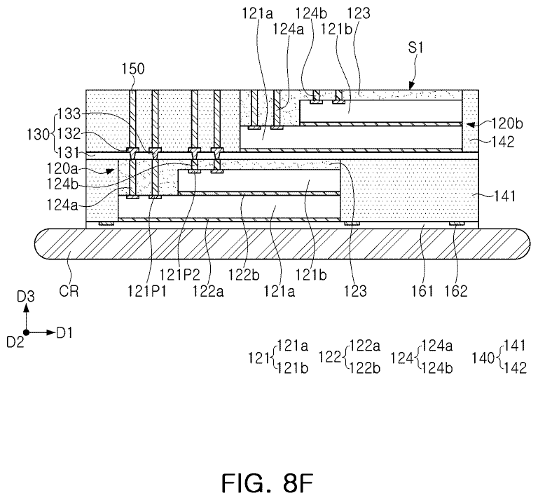

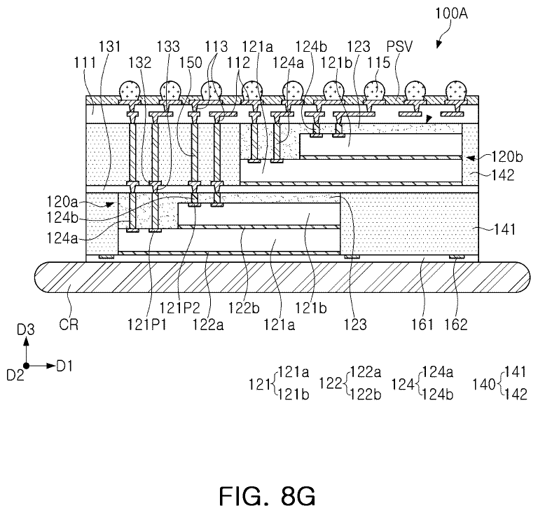

FIG. 7 is a flowchart illustrating a method (S100) of manufacturing a semiconductor package according to one or more example embodiments, and FIGS. 8A to 8G are drawings illustrating a method (S100) of manufacturing a semiconductor package of FIG. 7.

Referring to FIG. 7, the method (S100) of manufacturing a semiconductor package may include an operation of forming a cover layer and an alignment pattern on a carrier substrate (S101), an operation of attaching a first chip structure on the cover layer (S102), an operation of forming a first mold layer covering the first chip structure (S103), an operation of forming an interconnection structure on the first mold layer and the first chip structure (S104), an operation of forming posts on the interconnection structure (S105), an operation of attaching a second chip structure on the interconnection structure around the posts (S106), an operation of forming a second mold layer covering the posts and the second chip structure (S107), and an operation of forming a redistribution structure on the second mold layer and the second chip structure (S108).

Referring to FIGS. 7 and 8A, a cover layer 161 and an alignment pattern 162 may be formed on a carrier substrate CR. The carrier substrate CR may be a temporary support including a glass wafer, a curable resin layer, or the like. The cover layer 161 may be formed by, for example, coating and curing PID. The alignment pattern 162 may be formed by using a photolithography process, a plating process, or the like. The alignment pattern 162 may include a metal such as copper (Cu).

Thereafter, a first chip structure 120a may be attached on the cover layer 161. The first chip structure 120a may be placed at a position determined by using the alignment pattern 162 as an alignment key. The first chip structure 120a may be placed such that the first surface S1 of the first chip structure 120a on which the pillars 124 are exposed faces upwards. The cover layer 161 and the alignment patterns 162 may be formed on an entire upper portion of the carrier substrate CR, and a plurality of first chip structures 120a may be placed on the carrier substrate CR. However, for convenience of explanation, only the parts that make up a single semiconductor package are illustrated.

Referring to FIGS. 7 and 8B, a first mold layer 141 covering the first chip structure 120a may be formed. The first mold layer 141 may include a material the same as or similar to the gap-fill layer 123 of the first chip structure 120a. The first mold layer 141 may be formed by coating and curing a polymer material such as EMC on a carrier substrate CR, for example. The first mold layer 141 may be ground such that the first surface S1 of the first chip structure 120a is exposed.

Referring to FIGS. 7 and 8C, an interconnection structure 130 may be formed on the first mold layer 141 and the first chip structure 120a. The interconnection structure 130 may include an insulating layer 131, a connection layer 132, and connecting vias 133. The insulating layer 131 may be formed, for example, by applying and curing PID. The connection layer 132 and connecting vias 133 may be formed by performing an exposure process and a development process to form a via hole penetrating the insulating layer 131, and patterning a metal material on the insulating layer 131 using a plating process and an etching process.

Referring to FIGS. 7 and 8D, posts 150 may be formed on the interconnection structure 130. The posts 150 may be disposed on the connection layer 132 of the interconnection structure 130. The posts 150 may include, for example but not limited to, copper (Cu) or an alloy thereof. The posts 150 may include or be formed, for example, using a modified semi-additive process (MSAP) process. The posts 150 may include an electroplating seed layer formed on the surface of the connection layer 132.

Referring to FIGS. 7 and 8E, a second chip structure 120b may be attached to the interconnection structure 130 around the posts 150. The second chip structure 120b may be placed at a position determined by using the alignment pattern 162 as an alignment key. The second chip structure 120b may be placed such that the first surface S1 of the second chip structure 120b faces upwards. It may be understood that the second chip structure 120b may include substantially the same components as the first chip structure 120a.

Referring to FIGS. 7 and 8F, a second mold layer 142 covering the posts 150 and the second chip structure 120b may be formed. The second mold layer 142 may include a material the same as or similar to the first mold layer 141. The second mold layer 142 may be formed, for example, by coating and curing EMC. The second mold layer 142 may be ground such that the first surface S1 of the second chip structure 120b is exposed.

Referring to FIGS. 7 and 8G, a redistribution structure 110 may be formed on the second mold layer 142 and the second chip structure 120b. The redistribution structure 110 may include an insulating layer 111, a redistribution layer 112, and redistribution vias 113. The insulating layer 111 may be formed by applying and/or curing PID. An exposure process and a development process using a photomask may be performed to form a via hole penetrating the insulating layer 111. Next, a deposition process, a plating process, an etching process, or the like may be used to form the redistribution layer 112 and redistribution vias 113. Connecting bumps 115 may be formed on the redistribution structure 110. The connecting bumps 115 may be formed by attaching flux and solder balls, and the like on the redistribution layer 112 and then using a reflow process. According to an example embodiment, a passivation layer (PSV) may be formed. The passivation layer (PSV) may include a solder resist. Thereafter, the semiconductor package 100A may be separated by a sawing process.

In this manner, according to the method (S100) of manufacturing a semiconductor package of an example embodiment, the semiconductor package 100A may be manufactured by a simplified process in light of the number of semiconductor chips 121. Therefore, the process risk may be reduced and the yield may be improved.

As set forth above, according to example embodiments, by stacking chip structures including a plurality of semiconductor chips, a semiconductor package and a method of manufacturing the same may be provided with reduced process difficulty and improved yield.

While example embodiments have been illustrated and described above, it will be apparent to those skilled in the art that modifications and variations could be made without departing from the scope of the present disclosure as defined by the appended claims and their equivalents.

What is claimed is:

1. A semiconductor package comprising:
a redistribution structure including a redistribution layer;
chip structures stacked vertically on the redistribution structure, and each including a first surface facing the redistribution structure and a second surface opposite the first surface;
an interconnection structure between the chip structures, the interconnection structure including a connection layer;
a mold layer covering at least portion of each of the chip structures;
at least one post within the mold layer and configured to electrically connect the connection layer and the redistribution layer; and
at least one connecting bump below the redistribution structure,
wherein each of the chip structures includes:
semiconductor chips, each including a front end and a back end opposite to the front end in a first direction, side ends opposite to each other in a second direction intersecting the first direction, and at least one connection pad adjacent to the front end and configured to electrically connect to the connection layer and the redistribution layer;
a gap-fill layer covering the semiconductor chips and defining the first surface of each of the chip structures; and
at least one pillar in the gap-fill layer, the at least one pillar extending from the at least one connection pad to the first surface, and
wherein the semiconductor chips respectively have different widths from the front end to the back end in the first direction.

2. The semiconductor package of claim 1, wherein each of the chip structures further includes a first side surface adjacent to the front end, a second side surface adjacent to the back end, a third side surface adjacent to a first side end among the side ends, and a fourth side surface adjacent to a second side end among the side ends, and
wherein the first side surface, the second side surface, the third side surface, and the fourth side surface are defined by at least one of the front end, the back end, and the side ends of each of the semiconductor chips, and a side portion of the gap-fill layer.

3. The semiconductor package of claim 2, wherein the back end of each of the semiconductor chips is aligned with the second side surface of a chip structure corresponding thereto.

4. The semiconductor package of claim 2, wherein the first side end of each of the semiconductor chips is aligned with the third side surface of a chip structure corresponding thereto, and
wherein the second side end of each of the semiconductor chips is aligned with the fourth side surface of the chip structure corresponding thereto.

5. The semiconductor package of claim 1, wherein a largest width among widths of the semiconductor chips in the first direction is the same as a width of the gap-fill layer in the first direction.

6. The semiconductor package of claim 1, wherein back ends of the semiconductor chips are coplanar with each other.

7. The semiconductor package of claim 1, wherein front ends of the semiconductor chips are offset such that the at least one connection pad is exposed in a vertical direction.

8. The semiconductor package of claim 1, wherein the chip structures are offset such that the at least one pillar is exposed in a vertical direction.

9. The semiconductor package of claim 1, wherein each of the semiconductor chips further includes a lower surface on the at least one connection pad and an upper surface opposite to the lower surface, and
wherein each of the chip structures further includes an attachment film on the upper surface of each of the semiconductor chips.

10. The semiconductor package of claim 1, wherein the redistribution structure further includes at least one redistribution via extending from the redistribution layer and contacting the at least one pillar and the at least one post, and
wherein the interconnection structure further includes at least one connecting via extending from the connection layer and contacting the at least one pillar.

11. The semiconductor package of claim 10, wherein each of the at least one redistribution via and the at least one connecting via has a shape tapered toward the at least one pillar and the at least one post corresponding thereto.

12. A semiconductor package comprising:
a redistribution structure including a redistribution layer;
chip structures vertically stacked on the redistribution structure;
an interconnection structure between the chip structures and including a connection layer;
a mold layer surrounding the chip structures; and
at least one post within the mold layer and configured to electrically connect to the redistribution layer and the connection layer,
wherein each of the chip structures includes:
a first semiconductor chip including at least one first connection pad, a first front surface of the first semiconductor chip being on the at least one first connection pad and facing the redistribution structure;
a second semiconductor chip including at least one second connection pad and being on the first front surface of the first semiconductor chip, a second front surface of the second semiconductor chip being on the at least one second connection pad and facing the redistribution structure;
a gap-fill layer covering the first front surface and the second front surface;
at least one first pillar penetrating the gap-fill layer and respectively connected to the at least one first connection pad; and
at least one second pillar penetrating the gap-fill layer and respectively connected to the at least one second connection pad,
wherein the chip structures include a first chip structure on the interconnection structure, and a second chip structure between the redistribution structure and the interconnection structure, and
wherein the interconnection structure further includes an insulating layer between the connection layer and the first chip structure, and at least one connecting via penetrating the insulating layer and connecting the connection layer to the at least one first pillar and the at least one second pillar of the first chip structure.

13. The semiconductor package of claim 12, wherein a height of the at least one first pillar is greater than a height of the at least one second pillar.

14. The semiconductor package of claim 12, wherein the mold layer includes a first mold layer surrounding the first chip structure, and a second mold layer surrounding the second chip structure, and
wherein the semiconductor package further includes an alignment pattern on the first mold layer and the first chip structure, and a cover layer covering the alignment pattern.

15. The semiconductor package of claim 12, wherein the first semiconductor chip includes a first front end adjacent to the at least one first connection pad and a first back end opposite the first front end,
wherein the second semiconductor chip includes a second front end adjacent to the at least one second connection pad and a second back end opposite the second front end, and
wherein the first back end and the second back end are coplanar with each other.

16. The semiconductor package of claim 15, wherein a side portion of the gap-fill layer is coplanar with the first back end and the second back end.

17. A semiconductor package comprising:
a redistribution structure including a redistribution layer;
chip structures stacked vertically on the redistribution structure, and each including a first surface facing the redistribution structure and a second surface opposite the first surface;
an interconnection structure between the chip structures, the interconnection structure including a connection layer;
a mold layer covering at least portion of each of the chip structures;
at least one post within the mold layer and configured to electrically connect the connection layer and the redistribution layer; and
at least one connecting bump below the redistribution structure,
wherein each of the chip structures includes:
semiconductor chips vertically stacked;
a gap-fill layer covering at least a portion of each of the semiconductor chips; and
at least one pillar in the gap-fill layer, the at least one pillar configured to electrically connect the each of the semiconductor chips to the connection layer or the redistribution layer.

18. The method of claim 17, wherein the semiconductor chips respectively have different widths in a horizontal direction.

19. The method of claim 17, wherein each of the semiconductor chips includes a front end adjacent to at least one connection pad, and a back end opposite to the front end, and
back ends of the semiconductor chips are vertically aligned with each other.

20. The method of claim 19, wherein front ends of the semiconductor chips are offset such that the at least one connection pad is vertically exposed.
